(19) United States
(12) Patent Application Publication
(10) Pub. No.: US 2014/0306686 A1
(43) Pub. Date: Oct. 16, 2014

(54) User Mountable Utility Location Antenna

(71) Applicant: ALAN DAVID HADDY, Naples, FL (US)

(72) Inventor: ALAN DAVID HADDY, Naples, FL (US)

(21) Appl. No.: 13/859,888

(22) Filed: Apr. 10, 2013

(51) Int. Cl. G01R 29/08

(52) U.S. Cl. CPC G01R 29/0878
USPC 324/76.11

(57) ABSTRACT

A utility location antenna arrangement for mounting to a user can include at least one antenna element, and the arrangement can be mounted to the user in a hands-free manner. At least a portion of the arrangement can be mounted to at least one of an article of clothing worn by the user and a body part of the user.

### BACKGROUND OF THE INVENTION

Utilities and services can be buried underground or located behind surfaces, such as walls, and can include pipes, conduits, natural gas, electricity, communications, and water lines. For various reasons, such as marking positions for avoidance thereof when excavating nearby areas, knowing the locations of such utilities can be advantageous to avoid damage thereto, property damage, personal injury, etc.

Buried assets can be located by electromagnetic detection techniques. Certain buried assets can radiate their own electromagnetic fields. Other buried assets require a transmitted signal to be applied to a conductor. This transmitted signal causes an eletromagnetic field to be generated around the conductor.

Handheld devices having one or more antennas can then be utilized to detect the presence of these electromagnetic fields, and location, depth, and direction information can be determined.

### SUMMARY OF THE INVENTION

It is, therefore, an object of the present invention to provide a user mountable utility location antenna or antennas.

In an exemplary embodiment, the present invention can be embodied in a utility location antenna arrangement for mounting, directly or indirectly, to a user in a hands-free manner, with the arrangement having at least one antenna element.

In an exemplary aspect of the present invention, at least a portion of the antenna arrangement can be mounted to an article of clothing worn by the user.

In another exemplary aspect of the present invention, at least a portion of the antenna can be mounted to the user's body.

In a further exemplary aspect of the present invention, at least a portion of the antenna arrangement can be combined with an article of clothing worn by the user.

In still another exemplary aspect of the present invention, an antenna element can be a cylindrically shaped top antenna horizontally oriented relative to a ground surface when the user is standing above the ground surface, with the arrangement further including a cylindrically shaped bottom antenna, horizontally oriented relative to the ground surface, and positioned below and in parallel with the top antenna, when the user is standing above the ground surface; and a cylindrically shaped middle antenna, vertically oriented relative to the ground surface, and positioned between and perpendicular to the top and bottom antennas, when the user is standing above the ground surface.

In a further exemplary aspect of the present invention, at least one of the top, bottom, and middle antennas can be mounted to an article of clothing worn by the user.

In another exemplary aspect of the present invention, at least one of the top, bottom, and middle antennas can be mounted to the user's body.

In another exemplary aspect of the present invention, an antenna element can be an omnidirectional antenna, which can be mounted to a body part of the user and/or an article of clothing worn by the user.

In still another exemplary aspect of the present invention, an arrangement can include plural antennas, such as plural omnidirection antennas, for example and not in limitation.

These and other exemplary aspects of the present invention are described herein.

### BRIEF DESCRIPTION OF THE DRAWINGS

The present invention is illustrated by way of example, and not in limitation, in the figures of the accompanying drawings, in which:

FIG. 1 illustrates an exemplary environment of the present invention.

FIG. 2 illustrates an exemplary embodiment of the present invention, in which a utility location antenna arrangement, can include at least one antenna, and can be mounted to a user.

FIG. 3 illustrates an exemplary antenna arrangement 100 mounted to a user's foot 105.

FIG. 4 illustrates an exemplary antenna arrangement 100 integrated into a sole 106 of a user's shoe 107.

FIG. 5 illustrates an exemplary indirect mounting, in which an article of clothing 108 can include a pocket 109, in which arrangement 100 can be indirectly mounted.

FIG. 6 illustrates an exemplary embodiment of the present invention, in which an arrangement can include first and second antenna elements 101d, 101e, with each element being mounted to respective legs 101a, 101b of a user.

### DETAILED DESCRIPTION OF THE INVENTION

The invention will now be described in more detail by way of example with reference to the embodiments shown in the accompanying figures. It should be kept in mind that the following described embodiments are only presented by way of example and should not be construed as limiting the inventive concept to any particular physical configuration, material, or order.

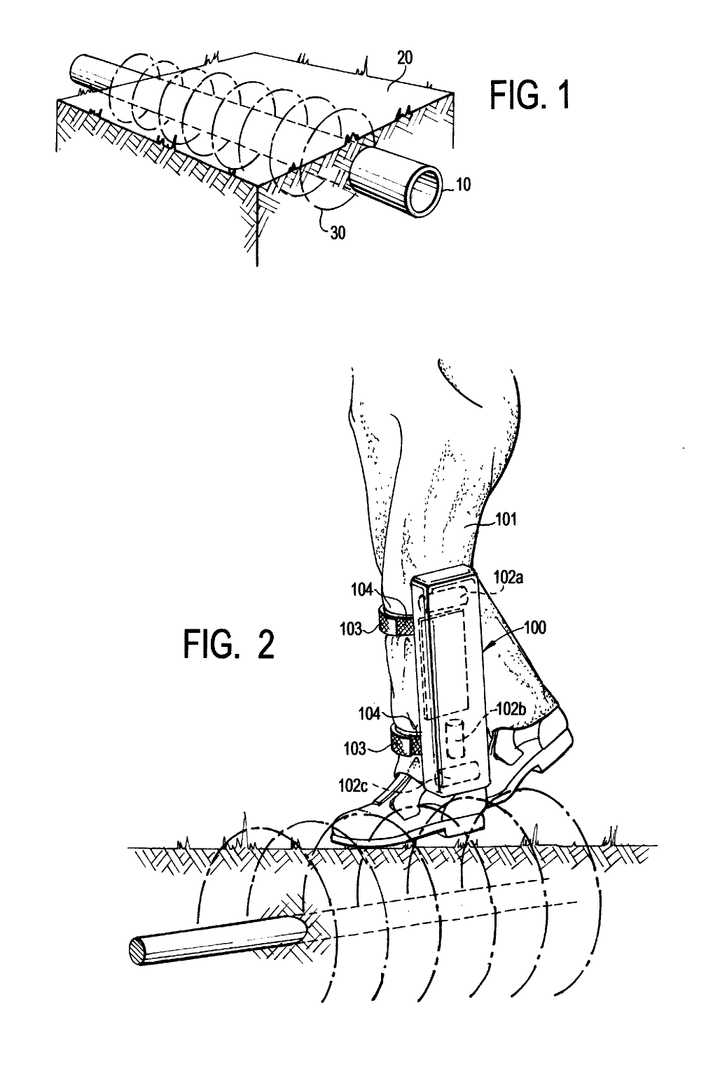

FIG. 1 illustrates an exemplary environment of the present invention, in which a utility 10 can be located below a ground surface 20, with the utility radiating an electromagnetic field 30 that extends above the ground surface, such that the field can be detected above the surface by an antenna arrangement.

FIG. 2 illustrates an exemplary embodiment of the present invention, in which a utility location antenna arrangement 100 for mounting to a user 101 can include at least one an antenna element 102a,102b, 102c, where the arrangement is mountable to the user in a hands-free manner. It should be noted that while FIG. 2 illustratively shows an arrangement 100 having a plurality of antennas 102a-c, an arrangement according to the present invention need only include at least one antenna. Thus, in accordance with the present invention, an antenna arrangement 100 can be based upon any one or more, in whole or in part, known or apparent antenna technologies, insofar as the same can detect the presence of an electromagnetic field; and therefore, is not necessarily limited to any particular antenna arrangement exemplarily illustrated or otherwise described herein. For example and not in limitation, an antenna arrangement and/or antenna element can be, or be based upon, any one or more, in whole or in part, of the following antenna technologies: a Wire Antenna, such as for example and not in limitation, a Short Dipole Antenna, a Dipole Antenna, a Half-Wave Dipole, a Broadband Dipole, a Monopole Antenna, a Folded Dipole Antenna, a Small Loop Antenna; a Travelling Wave Antenna, such as for example and not in limitation, a Helical Antenna, a Yagi-Uda Antenna, a Spiral Antenna; a Log Periodic Antenna, such as for example and not in limitation, a Bow Tie Antenna, a Log-Periodic Antenna, Log-Periodic Dipole Array; a Microstrip Antenna, such as for example and not in limitation, a Rectangular Microstrip Antenna, a Planar Inverted-F Antenna; a Reflector Antenna, such as for example and not in limitation, a Corner Reflector, a Parabolic Reflector; an Aperture Antenna, such as for example and not in limitation, an NFC Antenna, a Slot Antenna, a Cavity-Backed Slot Antenna, an Inverted-F Antenna, a Slotted Waveguide Antenna, a Horn Antenna, a Vivaldi Antenna, a Telescope Antenna; any other known or apparent antenna technology; and/or any variation thereof, insofar as the same can be utilized in the detection of an electromagnetic field associated with a utility.

In exemplary aspects of the present invention, the hands-free mounting of an antenna arrangement 100 to a user can obviate the requirement of the user to hold the arrangement with their hand or hands; and thus, advantageously allow the user to perform one or more additional hand-required tasks during a utility location survey, improve the safety of performing a survey, allow the user to focus on one or more other aspects arising or required during a survey, and/or to gain one or more other benefits during a survey.

In another exemplary aspect of the present invention, at least a portion of an antenna arrangement, in whole or in part, can be directly and/or indirectly mounted to a user, insofar as a functional arrangement is achieved.

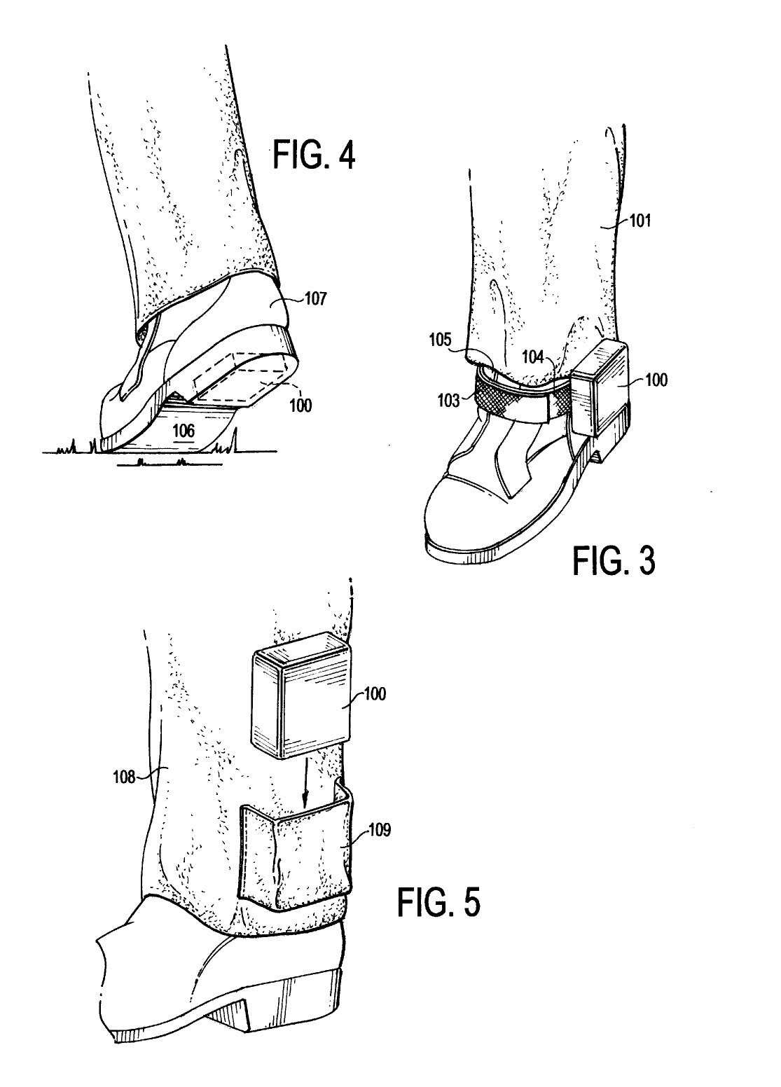

According to the present invention, direct mounting can include attaching the antenna arrangement to any part of a user's body via any known or apparent structure or structures that are functionally consistent with the present invention. For example and not in limitation, as illustrated in FIG. 2, antenna arrangement 100 can be directly mounted to a user's leg 101 via at least one strap 103, which can be secured via a VELCRO attachment 104. As illustrated in FIG. 3, antenna arrangement 100 can be mounted to a user's foot 105 via at least one strap 103, which can be secured via a VELCRO attachment 104. Notably, antenna arrangement 100 (or a portion thereof) can be attached to a user via any attachment technology consistent with the present invention, such as, for example and not in limitation, one or more of, in whole or in part, a snap, clasp, magnet, strap, buckle, etc., and further, may or may not attach over an article of clothing, such as a shirt sleeve, shoe, pant leg, etc. Moreover, exemplary body parts to which arrangement 100 can be attached include a user's leg (including the ankle), arm (including the wrist), hand, foot, waist, upper torso, or any other body part of a user, insofar as the attachment achieved is functionally consistent with the present invention.

According to the present invention, indirect mounting can include temporarily or permanently combining antenna arrangement 100 with an article of clothing that can be worn by user. In another exemplary aspect of the present invention, an article of clothing can include any type of covering that can be worn around or against any body part of a user, such as for example and not in limitation, a shoe, a sock, a shoe insert, a pant garment (including short and long pants), a shirt, a jacket, headwear, a wristband, a glove, etc. Further, such combining can be effectuated in any manner that is functionally consistent with the present invention. For example and not limitation, arrangement 100 can be stitched to or into an article; attached to an article via a strap, belt, pin, etc.; formed or otherwise provided within an article; inserted into a cavity of an article; and/or any combination thereof, in whole or in part. As illustrated in FIG. 4, arrangement 100 can be integrated into a sole 106 of a shoe 107. FIG. 5 illustrates another exemplary indirect mounting, in which an article of clothing 108 can include a pocket 109, in which arrangement 100 can be indirectly mounted.

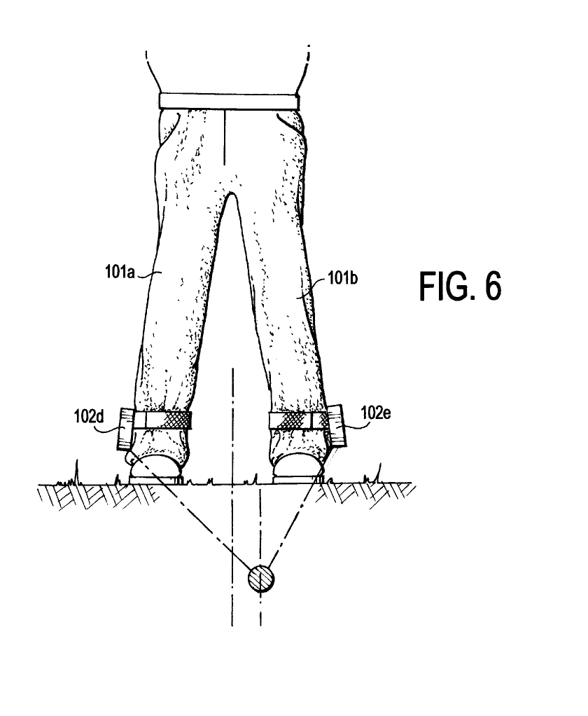

FIG. 6 illustrates another exemplary embodiment of the present invention, in which an arrangement can include first and second antenna elements 101d, 101e, with each element being mounted to respective legs 101a, 101b of a user.

In yet another exemplary aspect, where an antenna arrangement includes an omnidirectional antenna, a user can locate a utility by walking over the utility without the additional requirement of the antenna being oriented perpendicularly to the utility line.

It will be apparent to one of ordinary skill in the art that the manner of making and using the claimed invention has been adequately disclosed in the above-written description of the exemplary embodiments and aspects. It should be understood, however, that the invention is not necessarily limited to the specific embodiments, aspects, arrangement, and components shown and described above, but may be susceptible to numerous variations within the scope of the invention. Moreover, particular exemplary features described herein in conjunction with specific embodiments and/or aspects of the present invention are to be construed as applicable to any embodiment described within, enabled hereby, or apparent herefrom. Thus, the specification and drawings are to be regarded in a broad, illustrative, and enabling sense, rather than a restrictive one.

Further, it will be understood that the above description of the embodiments of the present invention are susceptible to various modifications, changes, and adaptations, and the same are intended to be comprehended within the meaning and range of equivalents of the appended claims.

Therefore, I claim:

1. A utility location antenna arrangement for mounting to a user, said arrangement comprising:
an antenna element;
wherein said antenna arrangement is mounted to the user in a hands-free manner.

2. The arrangement of claim 1, wherein at least a portion of said antenna arrangement is combined with an article of clothing worn by the user.

3. The arrangement of claim 1, wherein at least a portion of said antenna arrangement is mounted to a body part of the user.

4. The arrangement of claim 1, wherein at least a portion of said antenna arrangement is mounted below a waist of the user.

5. The utility location antenna arrangement of claim 1, wherein said antenna element is a cylindrically shaped top antenna horizontally oriented relative to a ground surface when the user is standing above the ground surface, and said arrangement further comprises:
a cylindrically shaped bottom antenna, horizontally oriented relative to the ground surface, and positioned below and in parallel with said top antenna, when the user is standing above the ground surface; and
a cylindrically shaped middle antenna, vertically oriented relative to the ground surface, and positioned between and perpendicular to said top and bottom antennas, when the user is standing above the ground surface;
wherein said top, bottom, and middle antennas are mounted to the user in a hands-free manner.

6. The arrangement of claim 5, wherein at least one of said top, bottom, and middle antennas is mounted to an article of clothing worn by the user.

7. The arrangement of claim 5, wherein at least one of said top, bottom, and middle antennas is mounted to a body part of the user.

8. The arrangement of claim 5, wherein at least one of said top, bottom, and middle antennas is mounted below a waist of the user.

9. The arrangement of claim 1, wherein said antenna element is an omnidirectional antenna.

10. The arrangement of claim 9, wherein said antenna element is mounted to an article of clothing worn by the user.

11. The arrangement of claim 9, wherein said antenna element is mounted to a body part of the user.

12. The arrangement of claim 9, wherein said antenna element is mounted below a waist of the user.

13. The arrangement of claim 1, wherein said antenna element is a first omnidirectional antenna, and said arrangement further comprises:
a second omnidirectional antenna;
wherein said first and second omnidirectional antennas are mounted to the user in a hands-free manner.

14. The arrangement of claim 13, wherein at least one of said first and second omnidirectional antennas is mounted to an article of clothing worn by the user.

15. The arrangement of claim 13, wherein at least one of said first and second omnidirectional antennas is mounted to a body part of the user.

16. The arrangement of claim 13, wherein at least one of said first and second omnidirectional antennas is mounted below a waist of the user.
